(19) United States
(12) Patent Application Publication
(10) Pub. No.: US 2007/0272917 A1
(43) Pub. Date: Nov. 29, 2007

(54) Process for Improved Cross-Linking of an Organic Semiconductor Layer by Using a Plastiser Containing Oxetane Groups

(76) Inventors: Carlo Domenico Cupertino, Cheshire (GB); Philip Ross Mackie, Cambridge (GB); Stephen George Yeates, Cheshire (GB)

Correspondence Address: Millen, White, Zelano & Branigan, PC, Ariington Courthouse Plaza I, 2200 clarendon Blvd. Suite 1400, Arlington, VA, 22201, US

(21) Appl. No.: 10/577,458

(22) PCT Filed: Oct. 28, 2004
(86) PCT No.: PCT/GB04/04534

§ 371 Date: May 14, 2007

(30) Foreign Application Priority Data
Oct. 30, 2003 (GB) 0325324.2

(51) Int. Cl. H01L 51/30; H01L 51/40

(52) U.S. Cl. 257/40; 438/99; 257/E51.028; 257/E51.029; 257/E51.032; 257/E21.46

(57) ABSTRACT

Semiconducting films are formed on a substrate by coating the substrate with a mixture of a semiconducting material and a substance which results in a Tg of the resulting mixture which is lower than that of the said material, and cross-linking the said material. Multilayer electronic devices may be produced by processes which comprise forming a cross-linked semiconducting film on a substrate in this way and forming a layer on the said film by solution or suspension deposition of a second film forming material in which the cross-linked semiconducting film is substantially insoluble in the solvent or suspending agent used in forming the second film. The invention may be used in making, for example, field effect transistors, light emitting diodes (LEDs), organic solar cells and organic lasers.

The present invention relates to a process for producing a semiconducting layer and an electronic device containing the same.

In multilayer organic electronic devices, for example organic field effect transistors (OFETs), organic light emitting diodes (OLEDs), organic solar cells and organic lasers, it may be desirable to include one or more organic semiconducting layers. The organic semiconducting layers may include, for example, light emitting layers or charge transporting layers for transporting holes and/or electrons.

Such organic semiconducting layers may be deposited by vacuum deposition of active molecules, that is, those responsible for the electrical or light emitting properties (if the molecules are of low molecular weight) but as this is difficult and expensive or impractical with many high molecular weight materials, it is desirable to deposit them from a dispersion or solution by coating a substrate and evaporating them to leave a consolidated film. Often it is desirable to form multi-layered structures in such devices, however, if a preceding layer is soluble or dispersible in the same liquid used to deposit a subsequent layer, intermingling of the layers or erosion may occur thereby degrading the performance of the device.

It has been proposed to use “orthogonal” solvent/dispersant pairs to overcome this, that is, solvents/dispersants are selected such that the solvent/dispersant used for the second etc. layer does not affect the first. However, a number of drawbacks exist. Such solvents may, because of the constraint in their choice, not be ideal for one or both layers and whilst some success may be obtained, it is still possible that some attack on the first layer may occur. If the layers in contact have similar solubility characteristics, for example because they are chemically similar, this approach may not be available. One solvent in such systems may be a polar liquid, water being typical, the other being non-polar. However, water is difficult to remove and if not removed may itself degrade the performance of the device.

A procedure has been disclosed in Muller et al, Synthetic Metals, 111-112 (2000) 31-34 in which a substrate is coated by spin coating with suitable cross-linkable active molecules and a photoinitiator, for example a photoacid catalyst, and the active molecules are then cross-linked by exposure to light of an appropriate wavelength. By this means a layer insoluble in a solvent used in the formation of a subsequent layer could be formed. Muller et al, Nature, 421 (2003) 829-833, apply a similar technique for forming RGB (red, green, blue) matrix displays by coating a substrate with a light emitting layer, cross-linking areas of the layer by light passed through a mask, washing off the remainder of the layer and repeating the process with the two other light emitters onto different areas thereby forming pixels. Both of these references describe the use of oxetane groups in the active molecules for cross-linking. The use of such groups is said to lead to low shrinkage (less than 5%) of the films as described by Nuyken et al, Macromol. Symp., 107 (1996) 125-138. Shrinkage can lead to microcracks which can result in leakage currents and may ultimately cause short circuits.

WO 97/33193 discloses arylamines having cross-linkable groups, films prepared from these materials and their use in electroluminescent and polymeric LEDs and as charge transport materials. That work does not claim or exemplify the use of oxetane units as the cross-linker group. WO 02/10129 describes the use of low molecular weight or polymeric compounds having at least one H group replaced by an oxetane unit of 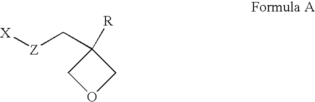
Formula A and specifies the use of these materials in cross-linked films as potential emissive layers in LEDs but also discusses their potential use in other multi-layered structures such as organic lasers, solar cells, wave-guides or integrated circuits. Further examples of this type have been described by Meerholz in Macromolecular Rapid Communications, 20 (2000) 224-228 and 21, (2000) 583-589 and also in Synth. Metals, 111-112 (2000) 31-34. These papers discuss the use of functionalised derivatives of N,N′-diphenyl-benzidine (TPD) which are linked together by non-conjugated groups to form a polymeric hole transport layer. These non-conjugated groups reduce the effectiveness of these materials as an organic semiconductor layer. Meerholz et al. also describes an extension of this work in Chem. Phys. Chem., 4 (2000) 207 in which the substituted TPD units are linked by different numbers of benzene spacers between the nitrogen's (1 or 2), the monomers are then cross-linked using oxetane coupling units to form a non-conjugated polymeric structure as described above.

In the prior art, when polymers are used having a glass transition temperature (Tg), higher than the processing temperature, it can be difficult to achieve acceptable degrees of cross-linking. In order to maximise the extent of the cross-linking reaction it is desirable to carry out the process at temperatures near to the Tg of the polymer. In this invention, it is preferred to use processing temperatures as near as practicable to ambient temperature and therefore, lower Tg compositions are preferred, for example of Tg 60 to 100° C.

An object of this invention is to optimise the cross-linking of an organic semiconducting layer to give an insoluble layer which can be over-coated and in which shrinkage or microcracking is minimised. Desirably, the cross-linking should not significantly affect the charge mobility or the electrical properties.

The invention comprises a process of producing a semiconducting layer by coating a substrate with a mixture of a semiconducting material and a substance which results in a Tg of the resulting mixture which prior to cross-linking is lower than that of the said semiconducting material, and cross-linking the said semiconducting material.

It is believed that this procedure permits the formation of less stressed layers in which microcracking is minimal (as assessed by optical means and by evaluation of electrical performance) even though the said substance may be consumed by reaction and/or evaporation and the layer may attain a higher Tg during the cross-linking reaction. Advantageously and unexpectedly, the use of the said substance does not significantly affect the electronic properties of the semiconducting material such as charge mobility.

The cross-linking is preferably carried out at a temperature near to the resulting Tg of the mixture, preferably within ±20° C. thereof.

Preferably, the said substance itself contains functional groups capable of cross-linking the semiconducting material (that is cross-linkable groups).

Preferably, the semiconducting material also contains functional groups capable of cross-linking it.

The semiconducting material preferably comprises an organic semiconducting material. The semiconducting material preferably comprises a semiconducting polymer, more preferably a π-conjugated semiconducting polymer, which has at least one cross-linkable group. The cross-linkable group is preferably linked to the semiconducting polymer by a linking group which comprises at least one, preferably at least four and more preferably at least six, for example six to twelve tetrahedral carbon atoms. The linking group may comprise, for example, a hydrocarbon or polyether chain. Preferably, the π-conjugated semiconducting polymer is cross-linked by reaction with the substance which, at the commencement of the cross-linking reaction, reduces the Tg of the π-conjugated semiconducting polymer. Preferably, the said substance also has a cross-linking functionality.

The π-conjugated semiconducting polymer preferably comprises, for example, π-conjugated units selected from at least one of poly(p-phenylene-vinylene), polyfluorene, poly-p-phenylene, polythiophene, polypyrrole or triarylamine units. The polymer preferably comprises 2 to 400 conjugated units, more preferably 5 to 200 conjugated units and most preferably 7 to 140 conjugated units. Preferably the π-conjugated semiconducting polymer comprises at least 5% and more preferably at least 40%, for example even more preferably at least 90%, of triarylamine units (including their associated cross-linking groups) by weight. Preferably the π-conjugated semiconducting polymer consists only of optionally substituted triarylamine units and their associated cross-linking groups as described in relation to Formula 7 below.

Blocks or units of π-conjugated semiconducting groups may be linked by non-conjugated linking groups if desired.

Whilst any one of many cross-linkable groups may be used, for example those described in WO 97/33193, the disclosure of which is incorporated herein by reference, it is preferred, especially if cross-linking is performed photochemically, to use oxetane groups as these perform well in photochemical reactions and are helpful in minimising excessive shrinkage and cracking of the layer. Preferably, the cross-linkable groups present on both the semiconducting polymer and the substance that lowers the Tg of the mixture comprise oxetane groups.

In this invention, a preferred cross-linkable group is an oxetane moiety of Formula A wherein:

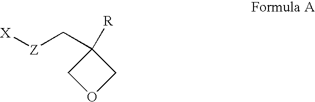

R is an optionally substituted straight chain or branched alkyl group, or a alkoxyalkyl or thioalkoxy group each of which may have from 1 to 20 carbon atoms, more preferably 1 to 10 carbon atoms and most preferably 1 to 6 carbon atoms; or R is an optionally substituted cyclic alkyl group which comprises from 2 to 20 carbon atoms, more preferably 2 to 10 carbon atoms and most preferably 2 to 6 carbon atoms.

Independently for each of the groups represented by R one or more non-adjacent carbon atoms may be replaced by —O—, —S—, —CO—, —COO—, or —O—CO—; and each group independently may be optionally substituted by for example but not limited thereto C₁-C₆-hydrocarbyl groups or a halogen that is, Cl, Br or F;

-Z- is —O—, —S—, —CO—, —COO—, —O—CO— or —CR^{a}R^{b}— (wherein R^{a} and R^{b} are each independently hydrogen, or an optionally substituted C₁₋₆-hydrocarbyl group optionally substituted by C₁₋₄-alkyl groups or halogens); preferably Z is —O— or —S—; most preferably Z is —O—; and

—X— is a bivalent group of formula —(CR^{c}R^{d})ₙ—, wherein R^{c} and R^{d} are each independently hydrogen or an optionally substituted C₁₋₆-hydrocarbyl group, wherein one or more non-adjacent carbon atoms may be replaced by —O—, —S—, —CO—, —COO—, —O— or CO, and wherein the optional substituents comprise C₁₋₄-alkyl groups or halogens; and wherein

n is an integer from 1 to 20, more preferably 3 to 10.

The π-conjugated semiconductor polymer preferably comprises one or more monomer units referred to hereinafter as ‘aromat units’ (as shown in Formula B). Each of these aromat units preferably comprises 1, 2, 3 or 4 aromatic monomers, and each ‘aromat unit’, may be independently the same or different. 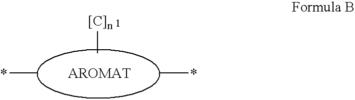
In each of the ‘aromat units’ of Formula B:
[C] is a cross-linkable group, preferably as described in relation to Formula A above; and
n¹ is 0, 1, 2, 3 or 4 provided that n¹ is not zero in every ‘aromat unit’; and
   * represents a functional group which is polymerisable such as for example a reactive halogen, Cl, Br, I, a boronic acid group, —B(OH)₂, a substituted boronic ester group of formula —B(OR¹¹)(OR¹²) wherein R¹¹ and R¹² are each independently H or C₁₋₄-alkyl groups, or a cyclic boronic ester of formula —B(OR¹³R¹⁴O) wherein R¹³ an R¹⁴ are each independently an optionally substituted C₂₋₁₄-hydrocarbyl group.

Preferably each ‘aromat unit’ comprises aromatic monomers as described in Formulae 1 to 7 as follows:
Formula 1

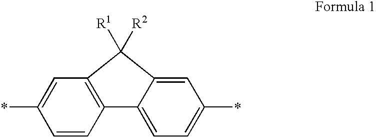

In Formula 1, R¹ and R² may be each independently a cross-linkable group (especially of Formula A), hydrogen, a fluorine atom or an optionally substituted C₁₋₂₀-alkyl, C₁₋₂₀-alkoxy, C₁₋₂₀-thioalkyl, acyl, aryl (for example phenyl) or hetero aryl group, or an optionally substituted secondary or tertiary alkylamine or arylamine of formula —N(R₄)(R₅), wherein R₄ and R₅ may be each independently hydrogen, C₁₋₂₀-alkyl, or an optionally substituted aryl, alkoxy or polyalkoxy group. The optional substituents on the R¹ and R² groups as well as on the R₄ and R₅ groups are preferably taken from the list comprising halogen, that is Cl, Br, I or F, C₁₋₄-alkyl or C₁₋₄alkoxy groups. The C₁₋₄-alkyl, or C₁₋₄-alkoxy groups may also be optionally substituted with fluorine.
Formula 2

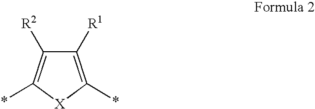

In Formula 2, X may be Se, Te, O, S or —N(R₆)—, more preferably O, S or —N(R₆)—, and most preferably S, wherein, R₆ represents hydrogen, optionally substituted C₁₋₁₂-alkyl, more preferably C₁₋₈-alkyl, optionally substituted aryl or an optionally substituted heteroaryl group and R¹ and R² are as previously described in relation to Formula 1.
Formula 3

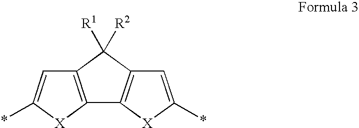

In Formula 3 R¹, R² and X are as previously described above in relation to Formulae 1 and 2 above respectively.
Formula 4

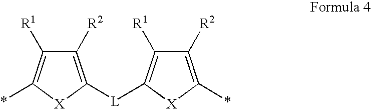

In Formula 4 R¹, R² and X are as previously described above in relation to Formula 1 and 2 respectively and L represents a π-conjugated linker group represented by —C(T₁)=C(T₂)—, —C≡C—, —N(R⁷)—, —N═N—, —N═C(R⁷)—, wherein T₁ and T₂ are each independently hydrogen, Cl, F, —C≡N or a C₁₋₄-alkyl group and R⁷ is hydrogen, an optionally substituted C₁₋₁₂-alkyl group, an optionally substituted aryl group, or optionally substituted heteroaryl group wherein the optional substituents comprise halogen, C₁₋₄-alkyl groups or C₁₋₄-alkoxy groups.
Formula 5

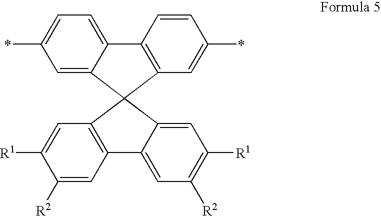

In Formula 5, each R¹ and R² which may be the same or different are each independently as specified previously for R¹ and R² in relation to Formula 1.
Formula 6

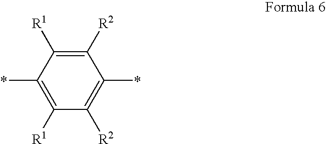

In Formula 6, each R¹ and R² which may be the same or different are each independently as specified previously for R¹ and R² in relation to Formula 1.
Formula 7

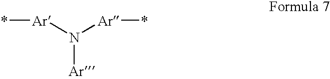

In Formula 7 the monomer is a tertiary amine unit, and the groups Ar′, Ar″ and Ar′″ are each independently optionally substituted aryl groups for example methyl substituted phenylene groups, or more preferably Ar′ and Ar″ are phenylene groups. Most preferably however Ar′ and Ar″ are unsubstituted aryl groups, for example phenylene groups. Ar′″ may be an optionally o- or p-substituted aryl group or an optionally substituted 5 or 6 membered heteroaryl group, as described in relation to Formula 2 above, optionally substituted with a cross-linkable group, especially a group of Formula A as also described above, hydrogen, alkyl, alkoxy, thioalkyl, acyl, aryl or substituted aryl group, fluorine, a cyano group or a nitro group.

In each of Formulae 1 to 7 * is a functional group as defined above in relation to Formula B.

Preferred classes of compounds for the semiconducting polymer include those containing π conjugated repeat units. The semiconducting polymer may comprise a homopolymer, copolymer or alternating block-copolymer of Formula 8: 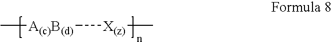
wherein A, B, . . . , X etc. each represent an ‘aromat unit ’ as defined above in relation to Formula B and (c), (d), . . . (z) each represent the fraction of the respective ‘aromat unit’ in the polymer. That is, (c), (d), . . . (z) etc. each represent the mole fraction of the amount of ‘aromat unit’ in the polymer of a value from 0 to 1 such that the total mole fraction of (c)+(d)+ . . . (z)=1. In Formula 8, n is the number of ‘aromat units’ comprising the π-conjugated semiconducting polymer and preferably comprises 2 to 100, more preferably 5 to 50 and most preferably 7 to 35. The conjugated repeat unit may, if desired, contain an emissive conjugated unit. The conjugated repeat units may contain a functionalised unit which can be used to modify the charge transport characteristics of the conjugated polymer and/or to provide a site to give cross-linking of the polymer chain to make it insoluble upon irradiation with UV light.

Preferably the ratio of the number of cross-linking groups in the π-conjugated polymer to the total number of monomer units in the π-conjugated polymer is 0.1 to 0.6 and more preferably 0.2 to 0.3. Any cross-linking groups of the substance which reduces the Tg of the polymer are additional thereto.

The quantity of the substance which reduces the Tg of the semiconducting material is preferably 5 to 60% by weight, more preferably at least 10%, even more preferably at least 25%, and still more preferably at least 40% by weight of the mixture of the said substance and the semiconducting material at the commencement of cross-linking. The Tg of the said mixture is preferably 60 to 100° C. for example about 80° C.

The substrate may include any underlying layer, electrode or separate substrate such as silicon wafer or polymer.

Photochemical cross-linking may be catalysed by UV photocatalysts, for example [4-{(2-hydroxytetradecyl)oxy}phenyl]iodonium hexafluoroantimonate. UV light frequencies of less than 380 nm are suitably used.

Cross-linking is preferably carried out at a temperature of 40 to 120° C. If carried out below 100° C. it is preferred to raise the temperature to 100 to 120° C. at the end of the reaction to complete the cross-linking process and to anneal the film. Cross-linking may be effected by light, heat or both.

Preferably the mixture according to the present invention is deposited from a solvent. In this form of the invention, the solution comprising the mixture is coated onto a substrate and the solvent is evaporated to form a layer or film. Preferably the mixture and the compounds making up the mixture are soluble in a wide range of organic solvents, for example without limitation, toluene, THF, ethyl acetate, dichloromethane, chlorobenzene, anisole and xylene. Thus, the mixture may be applied to a substrate as part of a device manufactured by various types of solution coating. The mixture can be applied to a substrate by a variety of coating or printing techniques such as dip coating, roller coating, reverse roll coating, bar coating, spin coating, gravure coating, lithographic coating (including photolithographic processes), ink jet coating (including continuous and drop-on-demand, and fired by piezo or thermal processes), screen coating, spray coating and web coating. A UV photoacid catalyst can be incorporated into the formulation at between 0.01 and 5 weight % on the polymer. Suitable catalysts are well known in the field, as for example disclosed in Nuyken et al., Macromolecular. Symp. 107,125, 1996 and references therein. In this present invention a preferred catalyst is [4-{(2-hydroxytetradecyl)oxy}phenyl]iodonium hexafluoroantimonate. The resulting layer or film can be cross-linked by irradiating the film with UV light (λ<380 nm) to form a solvent-insoluble layer which can subsequently be over-coated with other layers. Cross-linking may also be achieved by electron-beam lithography. This is particularly useful if a patterned layer is required, for example in order to produce pixels, but in other cases it may be desired to initiate the reaction by heat, free radicals or ionic mechanisms without the use of light (including visible, infra red and ultra violet radiation).

Deposition of the layer on a substrate is preferably carried out by dissolving or dispersing a π-conjugated semiconducting polymer and the substance which reduces the Tg and optionally a catalyst for cross-linking in a suitable solvent dispersion, coating the substrate with the solution, preferably under an increased gravitational field, evaporating the solvent and cross-linking the resulting film. The cross-linking is preferably initiated by light.

The invention also provides an electronic device which comprises a layer prepared by the process. The device may comprise for example one of an OFET, OLED, organic solar cell photovoltaic device or organic laser.

The invention also provides a process in which a multilayer device is produced by forming a first layer which is a cross-linked semiconducting layer on a substrate by the process above and forming a second layer on the first layer by solution or suspension deposition of a further layer forming material wherein the first cross-linked semiconducting layer is substantially insoluble in the solvent or suspending medium used to deposit the second layer.

The following are provided as examples of the present invention, but are non-limiting on the scope of the invention.

### EXPERIMENTAL

Part A: Synthesis of Monomers

All reactions were performed under anhydrous conditions and in an atmosphere of nitrogen in flame-dried glassware unless otherwise stated. Yields refer to isolated materials, found to be homogeneous chromatographically (HPLC or GC) and spectroscopically (¹H NMR) unless otherwise stated. All NMR spectra were run with CDCl₃ as solvent unless otherwise stated.

Precursors

### 3-Ethyl-3-chloromethyloxetane (Compound (1))

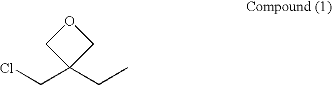

This material was synthesised by a standard route as described in H. Kenji, T. oji and K. Takayoshi PCT JP2001-226364 and H. Kenji, T. Koji and K. Takajoshi PCT JP2001-122866.

A flame-dried, nitrogen-purged 250 ml flanged flask fitted with a mechanical stirrer, dropping funnel, reflux condenser, thermometer and nitrogen inlet was charged with 3-ethyl-3-hydroxymethyloxetane (9.50 g, 81.8 mmol), triethylamine (9.09 g, 90 mmol) and anhydrous N,N-dimethylformamide (65 ml). The mixture was cooled to 0° C. under an atmosphere of nitrogen and stirred for 30 minutes. Methane sulfonyl chloride (9.84 g, 6.65 ml, 86 mmol) was added dropwise over 3 hours, keeping the temperature below 10° C. After this addition, the temperature of the mixture was raised to 20° C. and the mixture stirred for 3 hours. The temperature of the reaction mixture was again raised to 85° C. and the mixture stirred for a further 4 hours. After this time all triethylammonium chloride precipitate had reacted so that no cloudiness was evident in the reaction mixture.

Once the reaction was complete, water (250 ml) was added to the reaction mixture and the resultant mixture extracted three times with toluene (120 ml). The solvent was removed from the organic fraction in-vacuo and the crude residue purified by vacuum distillation [83-84° C. at 35 mm Hg] to yield the pure product. Yield=3.542 g, 32.2%. ¹H NMR: δ 4.43 (s, 4H, OCH₂); 3.85 (s, 2H, CH₂Cl); 1.85 (q, 2H, CH₂); 0.95 (t, 3H, CH₃).

### 8-(4-Bromobenzyloxy)octan-1-ol (Compound (2))

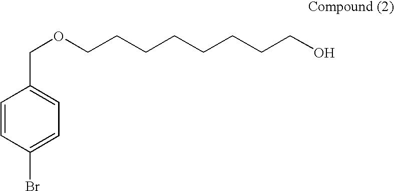

Into a flame-dried, nitrogen-purged, 250 ml flanged flask fitted with a mechanical stirrer, dropping funnel, reflux condenser, thermometer and nitrogen inlet was placed sodium hydride (4.50 g, 0.11 mol, 60% suspension in mineral oil, previously washed with hexane) suspended in dry N,N-dimethylformamide (150 ml) under a nitrogen atmosphere. A solution of 1,8-octanediol (14.65 g, 0.10 mol) in dry N,N-dimethylformamide (100 ml) was slowly added at 40° C., and the mixture stirred until evolution of hydrogen was complete. A solution of 4-bromobenzylbromide (25.00g , 0.10 mol) in dry N,N-dimethylformamide (100 ml) was then added simultaneously with potassium iodide (1.66 g, 0.01 mol). The mixture was stirred at 90° C. for 24 hours before being cooled to room temperature and diluted with diethyl ether (900 ml). The organic solution was washed twice with distilled water (400 ml), dried over magnesium sulfate and the solvent removed in-vacuo. The crude residue was purified by column chromatography [SiO₂, toluene-ethylacetate 7:3]. Yield=6.315 g, 20.0%. ¹H NMR: δ 7.50, 7.20 (AA′BB′, 4H); 4.45 (s, 2H, benzylic CH₂); 3.65 (t, 2H, CH₂); 3.45 (t, 2H, ethyl CH₂); 1.55 (m, 4H, alkyl); 1.35 (m, 8H, alkyl).

### 8-(4-Bromophenoxy)octan-1-ol (Compound (3))

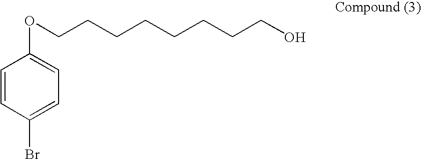

In a flame-dried, nitrogen-purged, 250 ml flanged flask fitted with a mechanical stirrer, dropping funnel, reflux condenser, thermometer and nitrogen inlet was placed 4-bromophenol (7.4456 g, 0.043 mol), 8-bromooctan-1-ol (10.00 g, 0.048 mol) and dry N,N-dimethylformamide (100 ml) under a nitrogen atmosphere. To this mixture was added potassium carbonate (26.3981 g, 0.191 mol) and the resultant mixture heated to 70° C. under a nitrogen atmosphere and stirred overnight.

After this time, the solvent was removed by first adding hexane and washing with water and then by removing the hexane in-vacuo to yield the crude product The crude residue was purified by column chromatography [SiO₂, hexane-dichloromethane 1:1]. Yield=10.51 g, 81.1%. ¹H NMR: δ 7.40, 6.75 (4H, AA′BB′, phenyl); 5.30 (s, 1H, OH); 3.95 (t, 2H, CH₂O); 3.65 (t, 2H, CH₂O); 1.75 (quintet, 2H, CH₂); 1.55 (m, 2H, alkyl); 1.45 (m, 4H, alkyl); 1.35 (m, 4H, alkyl).

### 3-[8-(4-Bromobenzyloxy)octyloxymethyl]-3-Ethyloxetane (Compound (4))

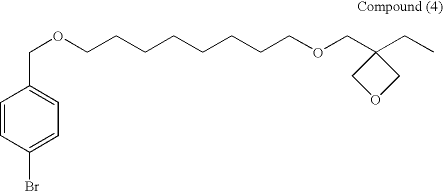

In a flame-dried, nitrogen-purged, 250 ml flanged flask fitted with a mechanical stirrer, dropping funnel, reflux condenser, thermometer and nitrogen inlet was placed sodium hydride (1.20 g, 30 mmol, 60% suspension in mineral oil, previously washed with hexane) suspended in dry N,N-dimethylformamide (70 ml) under a nitrogen atmosphere. A solution of 8(4-bromobenzyloxy)octan-1-ol (6.30 g, 20 mmol) in dry N,N-dimethylformamide (25 ml) was slowly added at 40° C., and the mixture stirred until evolution of hydrogen was complete. 3-Ethyl-3-chloromethyloxetane (2.963 g, 22 mol) was then added simultaneously with potassium iodide (0.166 g, 1.0 mmol). The mixture was stirred at 90° C. for 24 hours before being cooled to room temperature and diluted with diethyl ether (700 ml). The organic solution was washed twice with distilled water (180 ml), dried over magnesium sulfate and the solvent removed in-vacuo. The crude residue was purified by column chromatography [SiO₂, toluene-ethylacetate 9:1]. Yield=5.4449 g, 65.9%. ¹H NMR: δ 7.50, 7.10 (AA′BB′, 4H, phenyl); 4.45 (d, 4H, CH₂O); 4.35 (d, 2H, CH₂O); 3.55 (s, 2H, CH₂O); 3.45 (t, 4H, CH₂O); 1.85 (q, 2H ethyl); 1.60 (m, 4H, CH₂); 1.35 (m, 8H, alkyl); 0.90 (t, 3H, ethyl).

### 3-[8-(4-Bromophenoxy)octyloxymethyl]-3-Ethyloxetane (Compound (5))

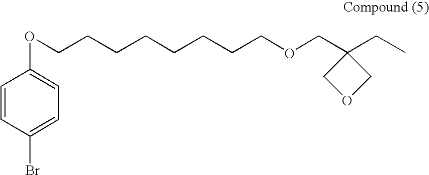

A similar method to that described for the synthesise of compound (4) was also used in this preparation. Sodium hydride (2.0977 g, 52.4 mmol, 60% suspension in mineral oil, previously washed with hexane) suspended in dry N,N-dimethylformamide (120 ml) was reacted with a solution of 8-(4-bromophenoxy)octan-1-ol (10.51 g, 34.9 mmol) in dry N,N-dimethylformamide (40 ml) and, 3-ethyl-3-chloromethyloxetane (5.170 g, 38.4 mol) with potassium iodide (0.290 g, 1.745 mmol). The crude residue was purified by column chromatography [SiO₂, toluene-ethylacetate 9:1]. Yield=2.8118 g, 20.2%. ¹H NMR: δ 7.35, 6.75 (AA′BB′, 4H, phenyl); 4.50 (d, 2H, CH₂O); 4.40 (d, CH₂O); 3.90 (t, 2H, CH₂O); 3.55 (s, 2H, CH₂O); 3.40 (t, 2H, CH₂O); 1.75 (m, 4H, alkyl); 1.50 (m, 2H, alkyl); 1.35 (m, 8H, alkyl) and 0.90 (t, 3H, CH₃).

### {4-[8-(3-Ethyloxetane-3-methoxy)octyloxymethyl]phenyl}diphenylamine (Compound (6))

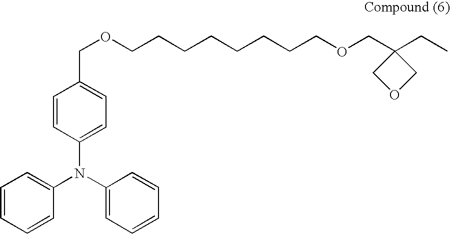

Into a flame-dried, nitrogen-purged, 250 ml flanged flask fitted with a mechanical stirrer, dropping funnel, reflux condenser, thermometer and nitrogen inlet was placed a solution of diphenylamine (2.231 g, 0.0132 mol), 3-[8-(4-bromobenzyloxy)octyloxymethyl]-3-ethyloxetane (5.44 g, 0.0132 mol) and sodium tert-butoxide (3.81 g, 0.0397 mol) in dry degassed toluene (80 ml) under a nitrogen atmosphere. A solution of tris(dibenzylidene acetone)dipalladium (0) Pd₂(dba)₃ (120.9 mg, 0.132 mmol) and tris-tert-butylphosphine (160 mg, 0.792 mmol) in dry degassed toluene (60 ml). The mixture was stirred at 100° C. for 24 hours until complete as shown by HPLC.

After this time the reaction mixture was cooled to room temperature and hexane (300 ml) was added. The solution was filtered and the solvent removed in-vacuo to yield an oil. The crude residue was purified by column chromatography [SiO₂, hexane-dichloromethane 1:1, gradient to dichloromethane-methanol 9:1]. Yield=5.25 g, 79.2%. Compound (6) was found to be pure by high performance liquid chromatography (HPLC). ¹H NMR: δ 7.25-6.85 (m, 14H, phenyl); 4.45 (m, 4H, CH₂O); 4.35 (d, 2H, CH₂O); 3.55 (s, 2H, CH₂O); 3.45 (m, 4H, CH₂O); 1.80 (q, 2H, CH₂); 1.6 (m, 4H, CH₂); 1.35 (, 8H, alkyl); 0.85 (t, 3H, CH₃).

### {4-[8-(3-Ethyloxetane-3-methoxy)octyloxy]phenyl}diphenylamine (Compound (7))

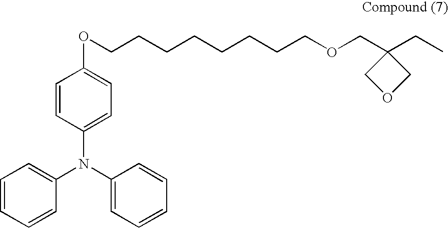

A similar method to that described for the synthesis of compound (6) was used in the preparation of this material, with diphenylamine (1.190 g, 7.04 mmol), 3-[8-(4-bromophenoxy)octyloxymethyl]-3-ethyloxetane (2.812 g, 7.04 mmol) and potassium tert-butoxide (2.370 g, 21.12 mol) in dry degassed toluene (60 ml) being reacted together with tris(dibenzylidene acetone)dipalladium (0) (Pd₂(dba)₃) (65 mg, 0.0704 mmol) and 2-(di-tert-butylphosphino)biphenyl (126 mg, 0.4224 mmol) as catalyst in dry degassed toluene (30 ml). The crude oil was purified by column chromatography [SiO₂, hexane: dichloromethane 1:1, gradient to dichloromethane:methanol 9:1]. Yield=2.73 g, 79.4%. ¹H NMR: δ 7.20-6.85 (m, 14H, phenyl); 4.45 (d, 2H, CH₂O); 4.35 (d, 2H, CH₂O); 3.95 (t, 2H, CH₂O); 3.55 (s, 2H, CH₂O); 3.45 (t, 2H, CH₂O); 1.75 (m, 4H, CH₂); 1.6 (m, 4H, CH₂); 1.45 (m, 2H, CH₂); 1.35 (m, 6H, alkyl); 0.90 (t, 3H, CH₃).

### (2,4-Dimethylphenyl)diphenylamine (Compound (8))

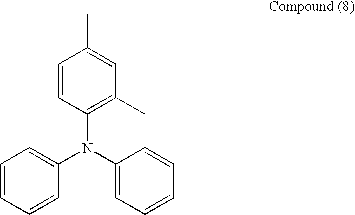

A similar method to that described for the synthesis of compound (6) was used in the preparation of this material. A solution of diphenylamine (22.838 g, 135.13 mmol), 4-bromo-m-xylene (25.0 g, 135.13 mmol) and sodium tert-butoxide (38.92 g, 405.39 mmol) in dry degassed toluene (300 ml) were reacted together with tris(dibenzylidene acetone)dipalladium (0) (Pd₂(dba)₃) (1.237 g, 1.3513 mmol) and 2-(di-tert-butylphosphino)biphenyl (2.419 g, 8.1078 mmol) as catalyst in dry degassed toluene (100 ml). The crude oil was purified by column chromatography [SiO₂, hexane]. Yield=28.638 g, 78.0%. ¹H NMR: δ 7.20-6.80 (m, 13H, phenyl); 2.35 (s, 3H, CH₃); 1.95 (s, 3H, CH₃).

### Synthesis of Tg-Lowering Substance (Reactive Plasticiser) 1,8-Bis(3-Ethyloxetane-3-methoxy)octane (Compound (9))

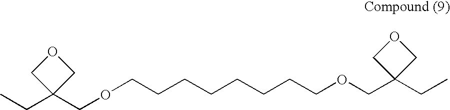

Into a flame-dried, nitrogen-purged, 250 ml flanged flask fitted with a mechanical stirrer, dropping funnel, reflux condenser, thermometer and nitrogen inlet was placed sodium hydride (1.41 g, 35.25 mmol, 60% suspension in mineral oil, previously washed with hexane) suspended in dry N,N-dimethylformamide (200 ml) under a nitrogen atmosphere. A solution of 1,8-octanediol (3.4318 g, 23.5 mmol) in dry N,N-dimethylformamide (70 ml) was slowly added at 40° C., and the mixture stirred until evolution of hydrogen was complete. 3-Ethyl-3-chloromethyloxetane (7.0 g, 51.85 mol) was then added simultaneously with potassium iodide (0.400 g, 2.36 mmol). The mixture was stirred at 90° C. for 24 hours before being cooled to room temperature and diluted with diethyl ether (700 ml). The organic solution was washed twice with distilled water (180 ml), dried over magnesium sulfate and the solvent removed in-vacuo. The crude residue was purified by column chromatography [SiO₂, toluene:ethylacetate 9:1]. Yield=1.01 g, 13.7%.

Monomers

### (1) Bis(4-Bromophenyl){4-[8-(3-Ethyloxetane-3-methoxy)octyloxymethyl]phenyl}amine (M1)

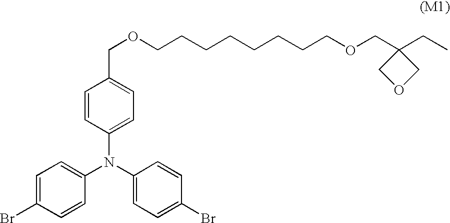

Into a flame-dried, nitrogen-purged, 250 ml flanged flask fitted with a mechanical stirrer, dropping funnel, reflux condenser, thermometer and nitrogen inlet was placed a solution of {4-[8-(3-Ethyloxetane-3-methoxy)octyloxymethyl]phenyl}diphenylamine (5.25 g, 10.5 mmol) in dry N,N-dimethylformamide (30 ml). The mixture was cooled to 0° C. and a solution of N-bromosuccinimide (3.738 g, 21 mmol) in dry N,N-dimethylformamide (20 ml) was added. The mixture was stirred and allowed to warm to room temperature over 24 hours.

After this time the reaction mixture was poured into distilled water (100 ml) and extracted three times with dichloromethane. The combined organic extracts were washed with copious distilled water, dried over magnesium sulfate and the solvent evaporated in-vacuo to yield the crude product. The product was then purified by flash column chromatography [SiO₂, dichloromethane:hexane 9:1 gradient to dichloromethane-methanol 9:1] to yield the pure product. Yield=3.10 g, 45.0%. ¹H NMR: δ 7.30-6.75 (m, 12H, phenyl); 4.35 (m, 4H, CH₂O); 4.25 (d, 2H, CH₂O); 3.45 (s, 2H, CH₂O); 3.35 (m, 4H, CH₂O); 1.65 (q, 2H, CH₂); 1.5 (m, 4H, CH₂); 1.25 (m, 8H, alkyl); 0.80 (t, 3H, CH₃).

### (2) Bis(4-Bromophenyl){4-[8-(3-Ethyloxetane-3-methoxy)octyloxy]phenyl}amine (M2)

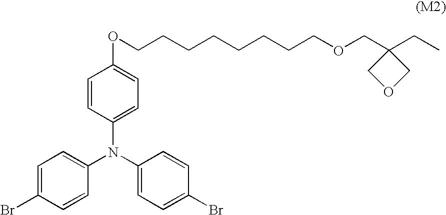

A similar method was used as described above for the synthesis of M1. {4-[8(3-Ethyloxetane-3-methoxy)octyloxy]phenyl}diphenylamine (2.73 g, 5.6 mmol) in dry N,N-dimethylformamide (30 ml) was reacted with N-bromosuccinimide (1.993 g, 11.2 mmol) in dry N,N-dimethylformamide (20 ml).

The product was purified by flash column chromatography [SiO₂, dichloromethane hexane 9:1 gradient to dichloromethane : methanol 9:1] to yield the pure product. Yield=2.07 g, 57.3%. ¹H NMR: δ 7.30, 6.90 (m, 8H, AA′BB′); 7.05, 6.85 (m, 4H, AA′BB′); 4.45 (m, 2H, CH₂O); 4.35 (m, 2H, CH₂O); 3.95 (t, 2H, CH₂O); 3.55 (s, 2H, CH₂O); 3.45 (t, CH₂O, 2H); 1.75 (m, 4H, alkyl); 1.60 (m, 2H, alkyl); 1.35 (m, 8H, alkyl); 0.85 (t, 3H, 0.85).

### (3) Bis(4-Bromophenyl)(2,4-dimethylphenyl)amine (M3)

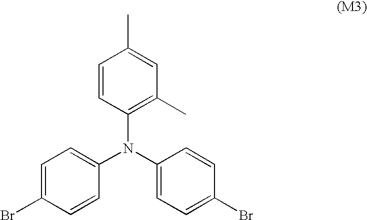

A similar method was used as described above for the synthesis of M1. (2,4-Dimethylphenyl)diphenylamine (17.39 g, 0.064 mol) in dry N,N-dimethylformamide (100 ml) was reacted with N-bromosuccinimide (3.738 g, 0.128 mol) in dry N,N-dimethylformamide (100 ml). The product was purified by flash column chromatography [SiO₂, dichloromethane:hexane 1:1] to yield the pure product. Yield=25.80 g, 94.0%. ¹H NMR: δ 7.35-6.80 (m, 11H, phenyl); 2.40 (s, 3H, CH₃); 2.05 (s, 3H, CH₃).

### (4) (2,4-Dimethylphenyl)-Bis(2-phenyl-4,4,5,5-tetramethyl-1,3,2-dioxaborolane)amine (M4)

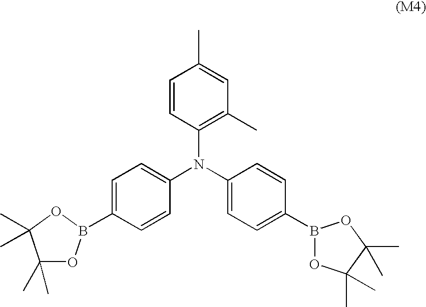

Into a flame-dried, nitrogen-purged, 250 ml three-necked flask fitted with a magnetic stirrer flea, septum cap, thermometer and nitrogen inlet was placed a solution of bis(4-bromomphenyl)(2,4dimethylphenyl)amine (12.50 g, 0.029 mol) and dry degassed tetrahydrofuran (60 ml). The solution was cooled to −78° C. under a nitrogen atmosphere and n-butyl lithium (34.75 ml, 0.087 mol, 2.5M solution in hexanes) was added dropwise, maintaining the temperature at −78° C.

The resulting yellow solution was stirred at −78° C. under nitrogen for 1 hour before 2-isopropoxy-4,4,5,5-tetramethyl-1,3,2-dioxaborolane (17.75 ml, 0.087 mol) was added. The mixture was then allowed to warm slowly to room temperature. The progress of the reaction was monitored by HPLC.

Upon complete reaction, the reaction mixture was evaporated in-vacuo and the residue dissolved in dichloromethane. The organic solution was washed three times with distilled water and dried over magnesium sulfate. The solvent was then removed in-vacuo to yield the crude product which was purified by flash column chromatography [SiO₂ hexane:ethylacetate 95:5] and by repeated recrystallisation from hexane and methanol. Yield=8.43 g, 55.4%. ¹H NMR: δ 7.65-7.00 (m, 11H, phenyl); 2.35 (s, 3H, CH₃); 2.05 (s, 3H, CH₃); 1.40 (s, 24H, pinacol CH₃).

Part B: Synthesis of Polymers

Polymers were prepared by the widely known Suzuki coupling procedure, as described in “The Suzuki cross-coupling.” by W. A. Herrmann, in Applied Homogeneous Catalysis with Organometallic Compounds (2nd Edition) (2002), 1 591-598, editors: B. Cornils and W. A. Herrmann, Wiley-VCH Verlag GmbH, Weinheim and by A. Suzuki in the Journal of Organometallic Chemistry (1999), 576(1-2), 147-168. Typical conditions for the polymerization of boronic acid or ester derivatised monomers with bromine derivatised monomers has also been described in detail, in for example: “Transition metal-catalyzed polycondensation and polyaddition” by W. Heitz, in Materials Science and Technology (1999), 20 (Synthesis of Polymers), 37-64, editor: A. D. Schlueter, Wiley-VCH Verlag GmbH, Weinheim, or in “The tenth anniversary of Suzuki polycondensation” by A. D. Schluter, in Journal of Polymer Science, Part A: Polymer Chemistry (2001), 39(10), 1533-1556.
Polymer P1.

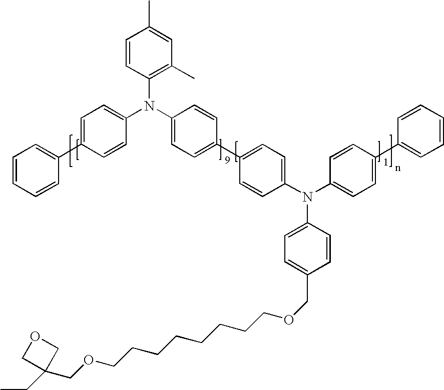

Copolymerisation of monomers M1 bis(4-bromophenyl){4-[8-(3-ethyloxetane-3-methoxy)octyloxymethyl]phenyl}amine (0.527 g, 0.8 mmol), M3 bis(4-bromophenyl)(2,4-dimethylphenyl)amine (1.381 g, 3.2 mmol) and M4 (2,4-dimethylphenyl)-bis(2-phenyl-4,4,5,5-tetramethyl-1,3,2-dioxaborolane)amine (2.10 g, 4 mmol) was achieved by the methods described above using the quantities indicated. The resultant polymer was obtained as an off-white solid, in a yield of 2.10 g, 89.4 %. ¹H NMR: δ 7.45-6.90 (m, phenyl); 4.45 (m, CH₂O ); 4.35 (m, CH₂O); 3.50 (s, CH₂O); 3.40 (m, CH₂O); 2.30 (s, CH₃); 2.05 (s, CH₃); 1.75 (g, CH₂); 1.6 (m, CH₂); 1.35 (m, alkyl); 0.90 (t, CH₃). GPC (THF, 1 ml/minute, PL gel Mixed D): Mw=41400 g/mol; Mn=8900 g/mol.
Polymer P2.

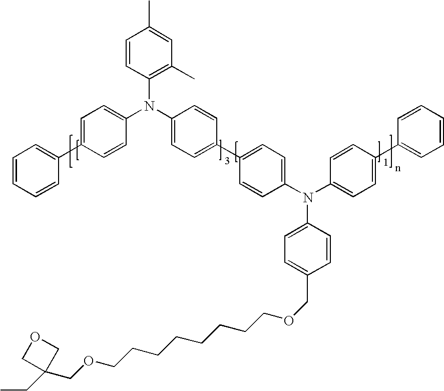

Copolymerisation of monomers M1 bis(4-bromophenyl){4-[8-(3-ethyloxetane-3-methoxy)octyloxymethyl]phenyl}amine (1,3180 g, 2.0 mmol), M3 bis(4-bromophenyl)(2,4-dimethylphenyl)amine (0.8632 g, 2.0 mmol) and M4 (2,4-dimethylphenyl)-bis(2-phenyl-4,4,5,5-tetramethyl-1,3,2-dioxaborolane)amine (2.10 g, 4 mmol) was achieved by the methods described above in the quantities indicated. The resultant polymer was obtained as an off-white solid. Yield 2.26 g, 85.8%. ¹H NMR: δ 7.45-6.90 (m, phenyl); 4.45 (m, CH₂O); 4.35 (m, CH₂O); 3.50 (s, CH₂O); 3.40 (m, CH₂O); 2.35 (s, CH₃); 2.05 (s, CH₃); 1.75 (q, CH₂); 1.55 (m, CH₂); 1.35 (m, alkyl); 0.85 (t, CH₃). GPC (THF, 1 ml/minute, PL gel Mixed D): Mw=35600g/mol; Mn=10100 g/mol.
Polymer P3.

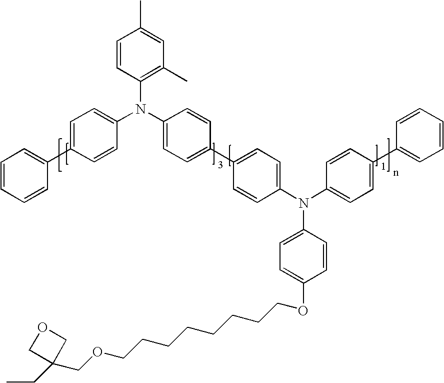

Copolymerisation of monomers M2 bis(4-bromophenyl){4-[8-(3-ethyloxetane-3-methoxy)octyloxy]phenyl}amine (2.07 g, 3.20 mmol), M3 bis(4-bromophenyl)(2,4-dimethylphenyl)amine (1.09 g, 2.53 mmol) and M4 (2,4-dimethylphenyl)-bis(2-phenyl-4,4,5,5-tetramethyl-1,3,2-dioxaborolane)amine (3.01 g, 5.73 mmol) was achieved by the methods described above in the quantities indicated. The polymer was obtained as an off-white solid, in a yield of 3.68 g, 96.8%. ¹H NMR: δ 7.40-6.80 (m, phenyl); 4.45 (m, CH₂O); 4.35 (m, CH₂O); 3.95 (m, CH₂O); 3.55 (s, CH₂O); 3.45 (m, CH₂O); 2.35 (s, CH₃); 2.05 (s, CH₃); 1.85 (m, CH₂); 1.55-1.25 (m, CH₂); 0.85 (t, CH₃). GPC (THF, 1 ml/minute, PL gel Mixed D): Mw=27520 g/mol; Mn=11421 g/mol.

Part C: Formulation Procedure

The polymers P1, P2 or P3 were blended with the reactive plasticiser molecules, 1,8-bis(3-ethyloxetane-3-methoxy)octane (Compound (9)), bis[1-ethyl(3-oxetanil)]methyl ether, (Compound 10) (obtained from Toagosei KK), or a non-reactive plasticiser of ethylene glycol dimethyl ether, at a variety of ratios (Table 1). All ratios are weight to weight ratios. The reactive plasticiser Compound (10) and unreactive plasticiser ethylene glycol dimethyl ether are commercially available from the sigma Aldrich Company Ltd. The reactive plasticiser Compound (9) was prepared as described in Experimental Part A: Synthesis of Monomers.

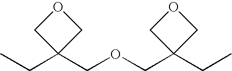

### Compound (10)-bis[1-ethyl(3-oxetanil)]methyl ether

A photoacid catalyst, (such as commercially available [4-{(2-hydroxytetradecyl)oxy}phenyl]phenyliodonium hexafluoroantimonate) was added to each formulation at 5.0% weight to weight with respect to the total weight of the polymer/reactive plasticiser mixture. A solvent, typically toluene, was then added to the mixture such that it was dissolved in the ratio of one part into 99 parts of solvent. After mixing the formulation on a mechanical shaker for 20 minutes, each formulation was spin coated onto a quartz slide at 1000 rpm for 20 seconds to give a film of approximately 100 nm thickness. To ensure complete drying the sample was placed in an oven for 20 minutes at 100° C. The UV-visible absorption spectrum of each film was then recorded using a Perkin Elmer Lambda 900 UV/VIS/NIR spectrometer. The sample was then mounted in a quartz sample holder and a flow of nitrogen gas was passed over the film. The holder and sample were heated to typically, 50 to 60° C. before being irradiated with a standard laboratory UV source (254 nm/360 nm) for 3 minutes. The film was then annealed at 100° C. for, suitably, 10 minutes before being cooled to ambient temperature and washed with tetrahydrofuran (THF) (2 mL). To ensure complete drying the sample was again placed in an oven for 10 minutes at 100° C. The UV-visible absorption spectrum of the film was then re-recorded and the intensity of the peak at λₘₐₓ noted. From a comparison of the intensities of the spectra at the λₘₐₓ of the cross-linked and uncross-linked films, a measure of the quantity of polymer retained on the quartz slide may be estimated given that at a particular wavelength, light is absorbed by a material according to the quantity of material comprising the absorbing layer. Thus, the extent of cross-linking can be determined for each formulation (Table 1).

TABLE 1
Example formulations of P1, P2 and P3 with selected reactive plasticisers

| | | | | | | Ethylene | |
|---|---|---|---|---|---|---|---|
| | | | | Compound | Compound | Glycol | % Cross- |
| Example | P1 | P2 | P3 | 10 | 9 | DME | linked |
| Formulation | (mg) | (mg) | (mg) | (mg) | (mg) | (mg) | Polymer |
| 1 | 0 | 80 | 0 | 80 | 0 | 0 | 97 |
| 2 | 80 | 0 | 0 | 80 | 0 | 0 | 50 |
| 3 | 0 | 80 | 0 | 0 | 80 | 0 | 93 |
| 4 | 80 | 0 | 0 | 0 | 0 | 0 | 8 |
| 5 | 0 | 80 | 0 | 0 | 0 | 0 | 41 |
| 6 | 0 | 75 | 0 | 25 | 0 | 0 | 73 |
| 7 | 80 | 0 | 0 | 0 | 80 | 0 | 59 |
| 8 | 0 | 25 | 0 | 75 | 0 | 0 | 87 |
| 9 | 0 | 80 | 0 | 0 | 0 | 80 | 84 |
| 10 | 0 | 75 | 0 | 28 | 0 | 0 | 78 |
| 11 | 75 | 0 | 0 | 30 | 0 | 0 | 33 |
| 12 | 80 | 0 | 0 | 0 | 0 | 80 | 41 |
| 13 | 0 | 0 | 80 | 80 | 0 | 0 | 88 |

From Table 1 it is evident that significantly higher quantities of polymer are retained on the quartz test slides when reactive plasticisers such as Compounds (9) or (10) are added to the formulation. When an un-reactive plasticiser such as ethyleneglycol dimethyl ether was used the amount of cross-linking was less but still improved compared to the case of no plasticiser. The best results were obtained when the weight to weight ratio of polymer to reactive plasticiser in the mixture was in the region of 50:50. The above results indicate that reactive plasticisers are advantageous in these compositions. The polymer P2, having a ratio of the number of cross-linking groups to the number of monomers in the polymer of 0.25 is cross-linked better than P1 (ratio=0.1).

Part D: Characterisation of Thin Films

Glass Transition Temperatures

Measurement of the glass transition temperatures of example materials was carried out by either conventional differential scanning calorimetry (DSC) or by modulated temperature DSC.

The Tg value for polymer P1 was determined to be 226° C. and the Tg value for polymers P2 and P3 determined to be 177° C.

Upon formulation of polymers P1, P2 or P3 with, for example, the reactive plasticiser, Compound (10), the Tg of the resultant material lowered from that of the pristine polymer, to give a typical Tg of 59° C.

Upon cross-linking, the Tg value expected to rise significantly as the material becomes a networked polymer, and accordingly no Tg value could be measured for cross-linked materials by either conventional or modulated temperature DSC.

Optical Microscopy of Films

Films were examined by optical microscopy under a crossed polariser prior to and after the cross-linking procedure described above. No evidence of shrinkage, microcracking or internally stressed films was observed in the films at up to 100× magnification.

Utility of Films in Electronic Devices

The formulated materials may be incorporated into electronic devices such as organic field effect transistors (OFETs) and organic light emitting diodes (OLEDs). As an example, a film of a formulation of the present invention was incorporated into an OFET device as described below.

Determination of the Field Effect Mobility

The field effect mobility of the materials was tested using the techniques described by Holland et al, J. Appl. Phys. Vol. 75, p. 7954 (1994).

In the following examples, a test field effect transistor was manufactured by using a Melinex polyester film substrate upon which were patterned Pt/Pd source and drain electrodes by standard techniques, for example shadow masking. The semiconductor formulation as described in experimental part C above, was spin coated onto the substrate at 1000 rpm for 20 seconds to yield a film of the order of 100 nm. To ensure complete drying the sample was placed in an oven for 20 minutes at 100° C. The semiconductor formulation was then cross-linked by the method described in part C. A solution of an insulator material with a low frequency permittivity (s) typically equal to 2.3 was then spin-coated onto the semiconductor giving a thickness typically in the range 0.5 μm to 1 μm. The sample was placed once more in an oven at 100° C. to evaporate solvent from the insulator. A gold gate contact was defined over the device channel area by evaporation through a shadow mask. To determine the capacitance of the insulator layer a number of devices were prepared which consisted of a non-patterned Pt/Pd base layer, an insulator layer prepared in the same way as that on the FET device, and a top electrode of known geometry. The capacitance was measured using a hand-held multimeter, connected to the metal either side of the insulator. Other defining parameters of the transistor are the length of the drain and source electrodes facing each other (W=25 mm) and their distance from each other (L=100 μm).

The voltages applied to the transistor are relative to the potential of the source electrode. In the case of a p type gate material, when a negative potential is applied to the gate, positive charge carriers (holes) are accumulated in the semiconductor on the other side of the gate insulator. (For an n channel FET, positive voltages are applied). This is called the accumulation mode. The capacitance/area of the gate insulator Cᵢ determines the amount of the charge thus induced. When a negative potential V_{DS} is applied to the drain, the accumulated carriers yield a source-drain current I_{DS} which depends primarily on the density of accumulated carriers and, importantly, their mobility in the source-drain channel. Geometric factors such as the drain and source electrode configuration, size and distance also affect the current. Typically a range of gate and drain voltages are scanned during the study of the device. The source-drain current is described by Equation 1.

$${I}_{DS} = \frac{μ {WC}_{i}}{L} ( ( {V}_{G} - {V}_{0} ) {V}_{DS} - \frac{{V}_{DS}^{2}}{2} ) + {I}_{Ω} , \qquad Equation 1$$

where V₀ is an offset voltage and I_{Ω} is an ohmic current independent of the gate voltage and is due to the finite conductivity of the material. The other parameters have been described above.

For the electrical measurements the transistor sample was mounted in a sample holder. Microprobe connections were made to the gate, drain and source electrodes using Karl Suss PH100 miniature probe-heads. These were linked to a Hewlett-Packard 4155B parameter analyser. The drain voltage was set to −20 V and the gate voltage was scanned from +20 to −60 V in 1 V steps. When |V_{G}|>|V_{DS}| the source-drain current varies linearly with V_{G}. Thus the field effect mobility can be calculated from the gradient of I_{DS} versus V_{G} given by Equation 2.

$$S = \frac{μ {WC}_{i} {V}_{DS}}{L} \qquad Equation 2$$

The field effect mobility of charge within formulated films before and after cross-linking were compared.

### Example 1

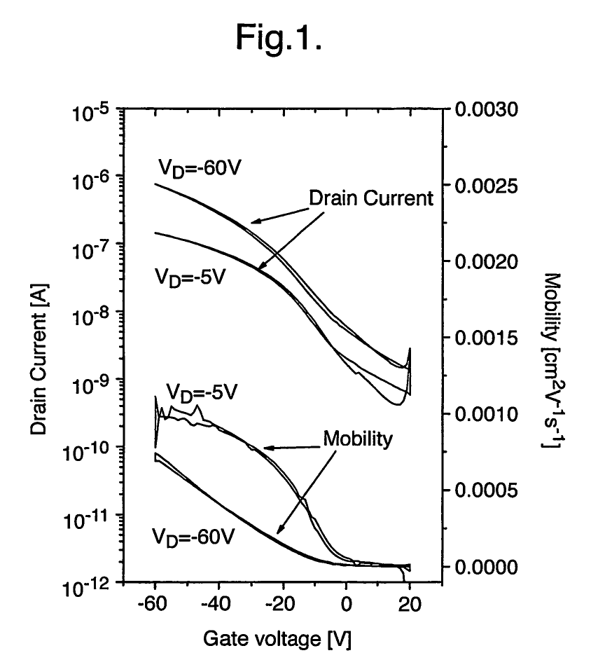

An FET device comprising an uncross-linked film of a formulation of the present invention was constructed. The field effect mobility of the material was found to be 1.16×10⁻³ cm²/Vs with a transfer curve as shown in FIG. 1.

### Example 2

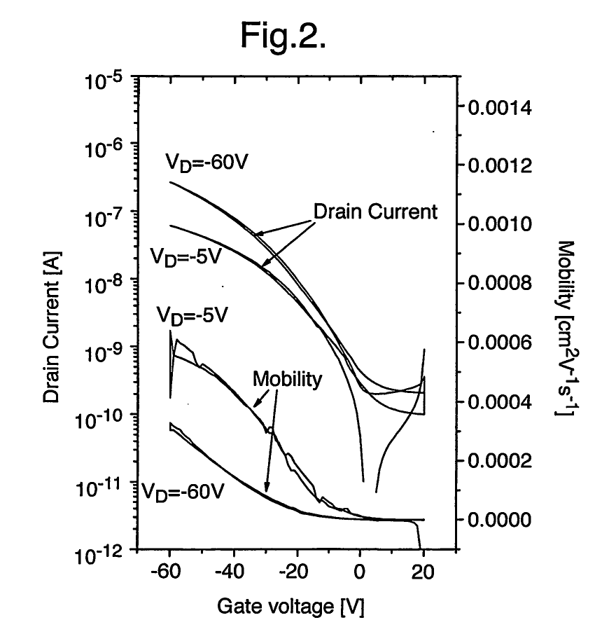

A FET device comprising a cross-linked film of a formulation of the present invention was constructed. The field effect mobility of the material was found to be 5.50×10⁻⁴ cm²/Vs with a transfer curve as shown in FIG. 2.

Thus it can be observed that cross-linking the semiconductor formulation does not have substantial adverse effects on the device characteristics of FET devices.

1. A process of producing a semiconducting layer by coating a substrate with a mixture of a semiconducting material and a substance which results in a Tg of the resulting mixture which prior to cross-linking is lower than that of the said semiconducting material, and cross-linking the said semiconducting material.

2. A process according to claim 1 in which the cross-linking is carried out at a temperature near to the resulting Tg of the mixture.

3. A process according to claim 1 in which the said substance itself contains functional groups capable of cross-linking the semiconducting material.

4. A process according to claim 1 in which the semiconducting material contains functional groups capable of cross-linking the semiconducting material.

5. A process according to claim 1 in which the semiconducting material comprises a π-conjugated semiconducting polymer which has at least one cross-linkable group.

6. A process according to claim 5 in which the π-conjugated semiconducting polymer comprises poly(p-phenylene-vinylene), polyfluorene, poly-p-phenylene, polythiophene, polypyrrole and/or triarylamine units.

7. A process according to claim 6 in which the π-conjugated semiconducting polymer comprises at least 5% and preferably at least 40%, more preferably at least 90% of triarylamine units including their associated cross-linking groups by weight.

8. A process according to claim 7 in which the π-conjugated semiconducting polymer consists only of optionally substituted triarylamine units and their associated cross-linking groups.

9. A process according to claim 8 in which the π-conjugated semiconducting polymer comprises 2 to 400 conjugated units, more preferably 5 to 200 conjugated units and most preferably 7 to 140 conjugated units.

10. A process according to claim 3 in which the functional cross-linkable groups comprise oxetane groups.

11. A process according to claim 1 in which the cross-linking is photochemically initiated.

12. A process according to claim 1 in which the mixture of the semiconducting material and the substance which results in a Tg of the resulting mixture which is lower than that of the said material is coated onto the substrate as a solution.

13. A process according to claim 3 wherein the ratio of the number of cross-linking groups in the π-conjugated polymer to the total number of monomer units in the π-conjugated polymer is 0.1 to 0.6 and more preferably 0.2 to 0.3.

14. A process according to claim 1 wherein the amount of said substance which reduces the Tg of the semiconducting material in the mixture is preferably 5 to 60% by weight, more preferably at least 10%, even more preferably at least 25% and still more preferably at least 40% by weight of the mixture of the said substance and the semiconducting material at the commencement of the cross-linking.

15. A process in which a multilayer device is produced by forming a first layer which is a cross-linked semiconducting layer on a substrate by a process according to claim 1 and forming a second layer on the first layer by solution or suspension deposition of a further layer forming material wherein the first cross-linked semiconducting layer is substantially insoluble in the solvent or suspending medium used to deposit the second layer.

16. A device which comprises a semiconducting layer produced by a process according to claim 1.
